(19) United States
(12) Patent Application Publication
(10) Pub. No.: US 2025/0226272 A1
(43) Pub. Date: Jul. 10, 2025

(54) SEMICONDUCTOR PACKAGE WITH A BLOCKING ELEMENT FORMED ON A SURFACE OF AN INSULATING LAYER

(71) Applicant: SAMSUNG ELECTRONICS CO., LTD., Suwon-si (KR)

(72) Inventors: Pilsung CHOI, Suwon-si (KR); Jiwon KANG, Suwon-si (KR); Geunwoo KIM, Suwon-si (KR); Taejun KIM, Suwon-si (KR); Hyunki KIM, Suwon-si (KR)

(73) Assignee: SAMSUNG ELECTRONICS CO., LTD., Suwon-si (KR)

(21) Appl. No.: 18/888,990

(22) Filed: Sep. 18, 2024

(30) Foreign Application Priority Data
Jan. 9, 2024 (KR) 10-2024-0003395

(51) Int. Cl. H01L 23/13; H01L 23/00; H01L 23/31; H01L 23/498; H01L 23/552

(52) U.S. Cl. CPC H01L 23/13; H01L 23/49816; H01L 23/49822; H01L 23/552; H01L 23/3107; H01L 24/16; H01L 24/32; H01L 24/73; H01L 2224/16225; H01L 2224/32225; H01L 2224/73204

(57) ABSTRACT

According to an aspect of the disclosure, a semiconductor package includes: a semiconductor chip; an insulating layer structure including a first surface facing the semiconductor chip and a second surface opposite to the first surface; a plurality of redistribution layers disposed within the insulating layer structure and electrically connected to the semiconductor chip; an encapsulant on the semiconductor chip and the first surface of the insulating layer structure; a plurality of connection conductors on the second surface of the insulating layer structure and electrically connected to the plurality of redistribution layers; and a shielding layer on a portion of the insulating layer structure and at least a portion of the encapsulant, in which the insulating layer structure further comprises a blocking element positioned on the second surface of the insulating layer structure and surrounding the connection conductors.

### CROSS-REFERENCE TO RELATED APPLICATION

This application claims benefit of priority to Korean Patent Application No. 10-2024-0003395 filed on Jan. 9, 2024 in the Korean Intellectual Property Office, the disclosure of which is incorporated herein by reference in its entirety.

### BACKGROUND

### 1. Field

The present embodiments of the disclosure relate to a semiconductor package.

### 2. Description of Related Art

In order to protect a user of an electronic device or semiconductor chip from electromagnetic interference (EMI), EMI shielding of a semiconductor package is required. EMI shielding serves to minimize electromagnetic interference. The shielding can reduce the coupling of radio waves, electromagnetic fields, and electrostatic fields. Research and development are being conducted to prevent defects caused by backspill and burrs that can occur when forming an EMI shielding film. Backspill may refer to a spreading of unwanted to material on a surface. A burr is a raised edge or small piece of material that remains attached to a workpiece after a process is performed.

### SUMMARY

An aspect of the present embodiment of the disclosure is to provide a semiconductor package with enhanced reliability.

According to an aspect of the disclosure, a semiconductor package, comprises: a semiconductor chip; an insulating layer structure below the semiconductor chip, the insulating layer structure comprising a first surface facing the semiconductor chip and a second surface opposite to the first surface; a plurality of redistribution layers disposed within the insulating layer structure and electrically connected to the semiconductor chip; an encapsulant on the semiconductor chip and the first surface of the insulating layer structure; a plurality of connection conductors on the second surface of the insulating layer structure and electrically connected to the plurality of redistribution layers; and a shielding layer on a portion of the insulating layer structure and at least a portion of the encapsulant, wherein the insulating layer structure further comprises a blocking element positioned on the second surface of the insulating layer structure and surrounding the plurality of connection conductors, wherein the blocking element has a stepped surface positioned on a different level from the second surface of the insulating layer structure, and wherein an end of the shielding layer is positioned between the stepped surface of the blocking element and the second surface of the insulating layer structure in a first direction perpendicular to a second direction in which the second surface of the insulating layer structure extends.

According to an aspect of the disclosure, a semiconductor package comprises: an insulating layer comprising a first surface and a second surface opposing each other and a third surface perpendicular to the first surface and the second surface; a plurality of redistribution layers within the insulating layer; a semiconductor chip facing the first surface of the insulating layer and electrically connected to the plurality of redistribution layers; an encapsulant on at least a portion of the semiconductor chip and the first surface of the insulating layer; a plurality of connection conductors on the first surface of the insulating layer and electrically connected to the plurality of redistribution layers; at least one dam structure on the second surface of the insulating layer and surrounding the plurality of connection conductors; and a shielding layer on a portion of the insulating layer and a portion of the encapsulant, wherein the second surface of the insulating layer comprises a first region positioned on a first side of the at least one dam structure, and a second region positioned on a second side of the at least one dam structure, and the plurality of connection conductors are arranged in the first region, wherein the second side of the at least one dam structure is closer to an edge of the insulating layer than the first side of the at least one dam structure, wherein the shielding layer comprises a body portion on the encapsulant and the third surface of the insulating layer, and a backspill portion on at least a portion of the second region of the second surface of the insulating layer, and wherein a thickness of the backspill portion in a first direction perpendicular to the second surface of the insulating layer is less than a thickness of the body portion in a second direction perpendicular to the third surface of the insulating layer.

According to an aspect of the disclosure, a semiconductor package, comprises: a semiconductor chip; an insulating layer below the semiconductor chip, the insulating layer comprising first surface facing the semiconductor chip, a second surface opposite to the first surface, and a third surface between the first surface and the second surface, wherein the third surface is perpendicular to the first surface and the second surface; a plurality of redistribution layers within the insulating layer and electrically connected to the semiconductor chip; an encapsulant on the semiconductor chip and the first surface of the insulating layer; a plurality of connection conductors on the second surface of the insulating layer and electrically connected to the plurality of redistribution layers; and a shielding layer on the third surface of the insulating layer and a first surface and second surfaces of the encapsulant, wherein the first surface of the encapsulant is perpendicular to the second surfaces of the encapsulant, wherein the second surface of the insulating layer comprises a first portion positioned on a first level, a second portion positioned on a second level higher than the first level, and surrounding the first portion, and a third portion positioned on a third level lower than the second level and surrounding the second portion; wherein the plurality of connection conductors are disposed on the first portion of the second surface of the insulating layer, and wherein an end of the shielding layer is positioned on a level, higher than the third level.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1A is a cross-sectional view illustrating a semiconductor package according to one or more exemplary embodiments;

FIG. 1B is a top view illustrating a semiconductor TT package according to one or more exemplary embodiments;

FIG. 1C is a bottom view illustrating a semiconductor package according to one or more exemplary embodiments;

FIG. 1D is an enlarged view of region ‘A’ in FIG. 1A;

FIGS. 2 to 4 are enlarged views of variations of region ‘A’ in FIG. 1A;

FIGS. 5 to 8 are bottom views illustrating semiconductor packages according to one or more exemplary embodiments;

FIG. 9A is a cross-sectional view illustrating a semiconductor package according to one or more exemplary embodiments;

FIG. 9B is a bottom view illustrating a semiconductor package according to one or more exemplary embodiments;

FIG. 9C is an enlarged view of region ‘B’ in FIG. 9A;

FIG. 10 is a bottom view illustrating a semiconductor package according to one or more exemplary embodiments;

FIG. 11A is a cross-sectional view illustrating a semiconductor package according to one or more exemplary embodiments;

FIG. 11B is a bottom view illustrating a semiconductor package according to one or more exemplary embodiments;

FIG. 11C is an enlarged view of region ‘C’ in FIG. 11A;

FIG. 12 is an enlarged view of a variation of region ‘C’ in FIG. 11A;

FIG. 13A is a cross-sectional view illustrating a semiconductor package according to one or more exemplary embodiments;

FIG. 13B is a bottom view illustrating a semiconductor package according to one or more exemplary embodiments;

FIG. 13C is an enlarged view of region ‘D’ in FIG. 13A;

FIGS. 14 and 15 are enlarged views of variations of region ‘D’ in FIG. 13A;

FIG. 16A to 16H are cross-sectional views of a process sequence illustrating a method of manufacturing a semiconductor package according to one or more exemplary embodiments;

FIG. 17A is enlarged views of region ‘E1’ and region ‘E2’ in FIG. 16H;

FIG. 17B is a bottom view with respect to the cross-section view of FIG. 16H;

FIGS. 18A and 18B are cross-sectional views of a process sequence illustrating a method of manufacturing a semiconductor package according to one or more exemplary embodiments;

FIG. 19 is a cross-sectional view illustrating a method of manufacturing a semiconductor package according to one or more exemplary embodiments;

FIG. 20 is an enlarged view of region ‘F’ in FIG. 19;

FIGS. 21A and 21B are cross-sectional views of a process sequence illustrating a method of manufacturing a semiconductor package according to one or more exemplary embodiments; and

FIG. 22 is an enlarged view of region ‘G’ in FIG. 21B.

### DETAILED DESCRIPTION

Hereinafter, exemplary embodiments of the present disclosure will be described with reference to the accompanying drawings. Terms, such as ‘upper,’ ‘upper portion,’ ‘upper surface,’ ‘lower,’ ‘lower portion,’ ‘lower surface,’ ‘side surface,’ and the like, may be understood as referring to the drawings, unless otherwise indicated by reference numerals.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

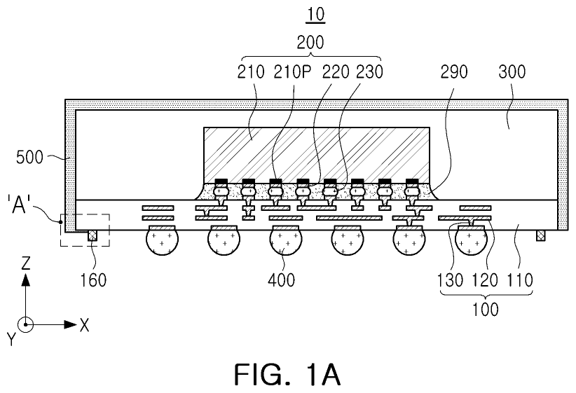

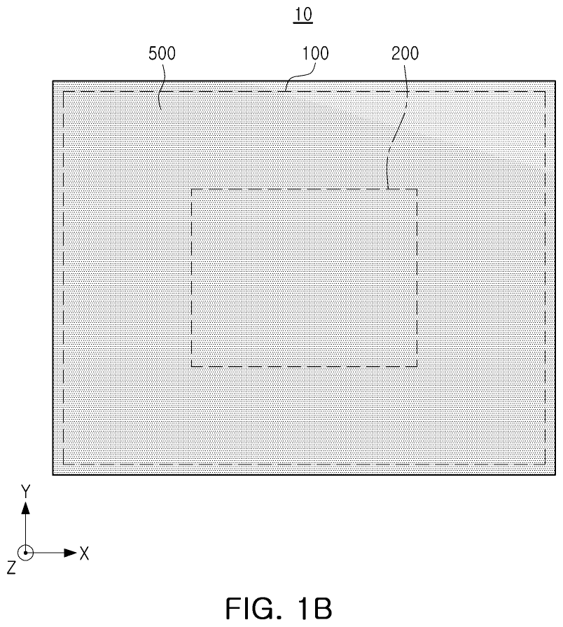

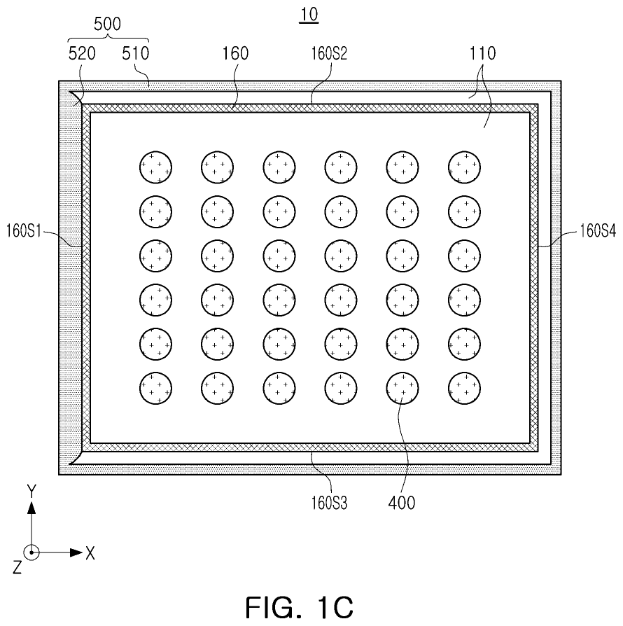

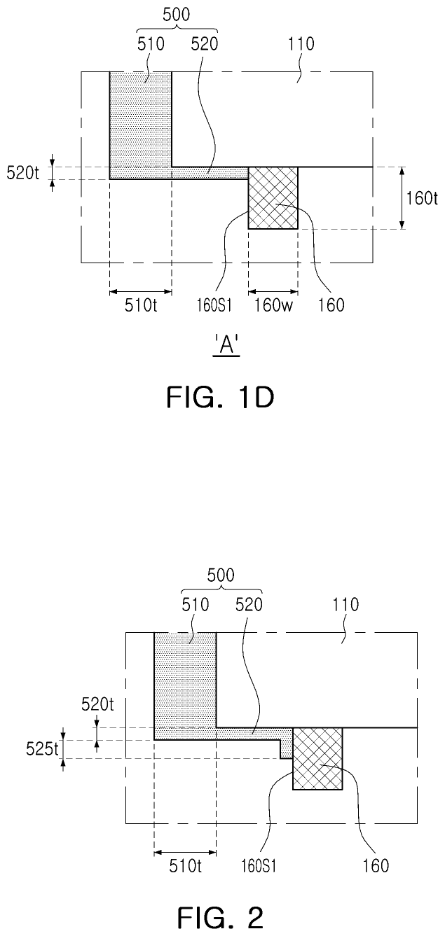

FIG. 1A is a cross-sectional view illustrating a semiconductor package 10 according to one or more exemplary embodiments. FIG. 1B is a top view illustrating a semiconductor package 10 according to one or more exemplary embodiments. FIG. 1B illustrates a top view of the semiconductor package 10 according to the exemplary embodiment of FIG. 1A, where one or more components illustrated in FIG. 1A but not illustrated in FIG. 1B are omitted for convenience of explanation. FIG. 1C is a bottom view illustrating a semiconductor package 10 according to one or more exemplary embodiments. FIG. 1C illustrates a bottom view of the semiconductor package 10 according to the embodiment of FIG. 1A. FIG. 1D is an enlarged view of region ‘A’ of the semiconductor package 10 according to the embodiment of FIG. 1A.

Referring to FIGS. 1A to 1D, the semiconductor package 10, according to one or more embodiments, may include a redistribution structure 100, a dam structure 160, a semiconductor chip structure 200, an encapsulant 300, connection conductors 400 and a shielding layer 500.

In one or more examples, the redistribution structure 100 may be a support substrate on which the semiconductor chip structure 200 is mounted. The redistribution structure 100 may include an insulating layer 110, redistribution layers 120, and redistribution vias 130.

In one or more examples, the insulating layer 110 may include an upper surface (e.g., first surface) facing the semiconductor chip structure 200 and a lower surface (e.g., second surface), opposite to the upper surface. Referring to FIG. 1C, the lower surface of the insulating layer 110 may have a rectangular shape including four sides. The insulating layer 110 may include an insulating resin. The insulating resin may include a thermosetting resin such as an epoxy resin, a thermoplastic resin such as polyimide, or a resin impregnated with an inorganic filler, for example, prepreg, Ajinomoto Build-up Film (ABF), FR-4 and Bismaleimide-Triazine (BT). For example, the insulating layer 110 may include a photosensitive resin such as PID (Photo-Imageable Dielectric). In one or more examples, the insulating layer 110 may include a plurality of insulating layers stacked in a vertical direction (Z-axis direction). Depending on the process, boundaries between a plurality of insulating layers (not shown) may vary.

As understood by one of ordinary skill in the art, a redistribution layer may be metal (e.g. copper) interconnects that electrically connect one part of a semiconductor package or chip to another. A redistribution layer may allow for creation of additional wiring on a chip, enabling the redistribution of I/O pads to different locations. These features provide enhanced chip-to-chip bonding by providing more flexible options for connecting integrated circuits (ICs) to other components. The redistribution layers 120 may be disposed on or within the insulating layer 110, and may redistribute a connection terminal 210P of a semiconductor chip 210. The redistribution layers 120 may include copper (Cu), aluminum (Al), silver (Ag), tin (Sn), gold (Au), nickel (Ni), lead (Pb), and titanium (Ti), or metal containing alloys thereof, for example. The redistribution layers 120 may perform various functions depending on the design. For example, the redistribution layers 120 may include a ground (GND) pattern, a power (PWR) pattern, and a signal(S) pattern. In one or more examples, the signal(S) pattern may be defined as a transmission path for various signals, for example, data signals, or the like, excluding the ground (GND) pattern, power (PWR) pattern, and the like. The redistribution layers 120 may include more or fewer redistribution layers than are shown in the drawing. The redistribution layers 120 disposed on the upper surface of the insulating layer 110 may be electrically connected to the connection terminals 210P of the semiconductor chip structure 200.

In one or more examples, the redistribution vias 130 may vertically extend in the insulating layer 110 and be electrically connected to the redistribution layers 120. For example, the redistribution vias 130 may interconnect the redistribution layers 120 on different levels. The redistribution vias 130 may include a signal via, a ground via and a power via. The redistribution vias 130 may include, for example, copper (Cu), aluminum (Al), silver (Ag), tin (Sn), gold (Au), nickel (Ni), lead (Pb), and titanium (Ti), or a metal material including alloys thereof. The redistribution vias 130 may be filled vias in which an interior of a via hole is filled with a metal material or conformal vias in which a metal material extends along an inner wall of a via hole.

In one or more examples, the dam structure 160 may be disposed on the lower surface of the insulating layer 110. The dam structure 160 may surround the connection conductors 400 disposed on the lower surface of the insulating layer 110. The dam structure 160 may be arranged to be spaced apart from the connection conductors 400 and side surfaces of the insulating layer 110 in horizontal directions (X-direction and Y-direction), and may be in a form of extending along outer edges of the lower surface of the insulating layer 110 and surrounding the connection conductors 400. The lower surface of the insulating layer 110 may include an inner region positioned inwardly, relative to the dam structure 160, and an outer region positioned outwardly, relative to the dam structure 160, and a lower surface of the dam structure 160 may be referred to as a stepped surface. The dam structure 160 may include inner surfaces facing the connection conductors 400 and outer surfaces 160S1, 160S2, 160S3 and 160S4, opposite to the inner surfaces. The outer surfaces 160S1, 160S2, 160S3 and 160S4 of the dam structure 160 may be arranged parallel to four side surfaces of the insulating layer 110, respectively, and the dam structure 160 may have a rectangular shape when viewed in a plan view. Each of the outer surfaces 160S1, 160S2, 160S3 and 160S4 may have a bar shape extending straight in the X- or Y-direction. Any one outer surface 160S1 of the dam structure 160 may be in contact with a backspill portion 520 of the shielding layer 500, which will be described later. In one or more examples, the inner region of the insulating layer 110 may be a portion of the insulating layer 110 that is between the inner surfaces of the dam structure 160. In one or more or more examples the outer region of the insulating layer 110 may be a portion of the insulating layer 110 that is between the outer surfaces of the dam structure 160 and a body portion 510 of the shielding layer 500 (described in further detail below).

In one or more examples, the dam structure 160 may include the same material as the insulating layer 110, and may include a photosensitive resin such as PID (Photo-Imageable Dielectric). Depending on the embodiments, the dam structure 160 may include a material different from that of the insulating layer 110. In a direction perpendicular to the lower surface of the insulating layer 110, a thickness 160t of the dam structure 160 may be 0.5 μm to 50 μm, and depending on the embodiments, may be 1 μm to 30 μm, 5 μm to 50 μm or 5 μm to 15 μm. If the thickness 160t of the dam structure 160 is less than 0.5 μm, a blocking ability of the dam structure 160 may decrease, thereby reducing reliability of the semiconductor package. If the thickness 160t of the dam structure 160 is more than 50 μm, the process cost may increase and the stability of the dam structure 160 may decrease, thereby reducing reliability of the semiconductor package. In a direction parallel to the lower surface of the insulating layer 110, a width 160w of the dam structure 160 may be 0.5 μm to 50 μm, and depending on the embodiments, may be 1 μm to 30 μm, 5 μm to 50 μm or 5 μm to 15 μm. If the width 160w of the dam structure 160 is less than 0.5 μm, a process difficulty may increase, and if the width 160w of the dam structure 160 is greater than 50 μm, a blocking ability of the dam structure 160 may decrease.

The dam structure 160 may block the shielding layer 500 from being formed in the inner region of the insulating layer and prevent contact between the shielding layer 500 and the connection conductors 400, thereby enhancing reliability of the semiconductor package.

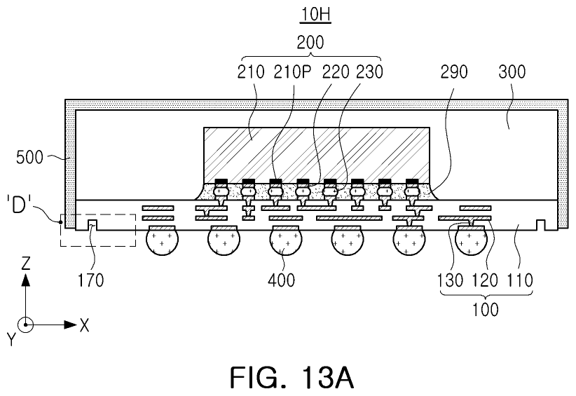

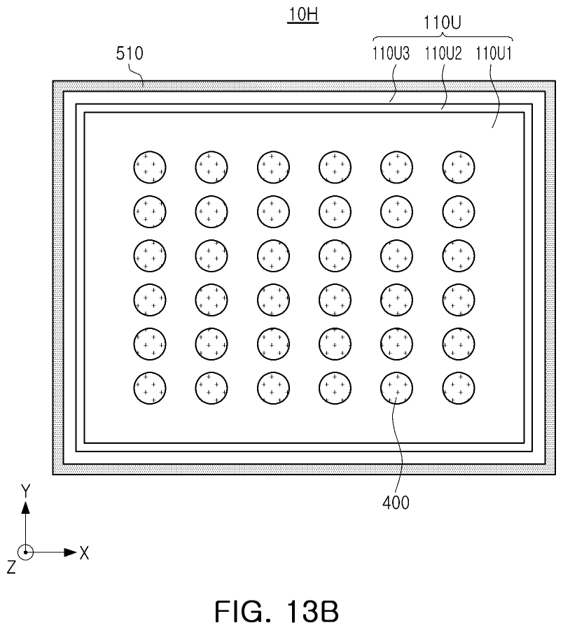

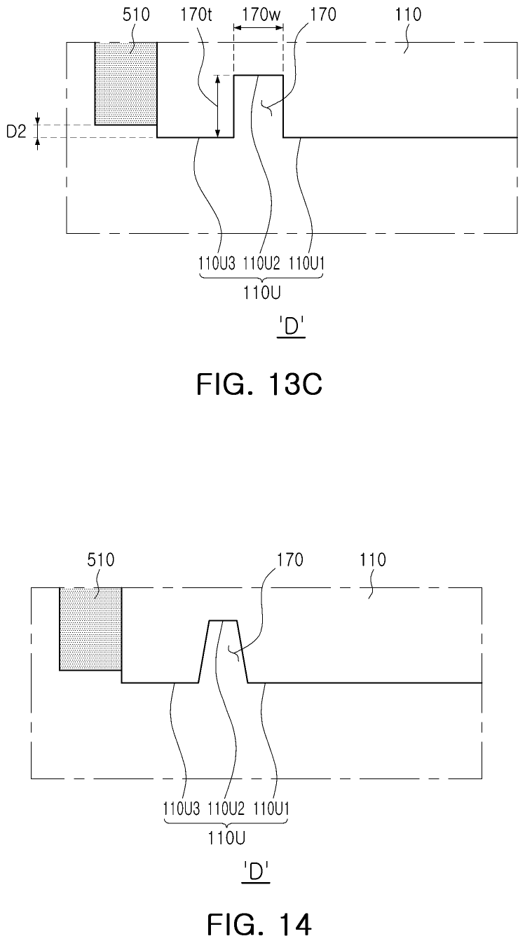

In one or more examples, the dam structure 160 may be collectively referred to as a blocking element together with a trench structure 170 (see FIGS. 13A and 13B), which will be described later. The dam structure 160 may be described as a configuration included in the insulating layer 110. In this case, a structure of the insulating layer 110 including the dam structure 160 may be referred to as an insulating layer structure 110 and 160. The insulating layer structure 110 and 160 may have a lower surface with a step due to the blocking element 160. The lower surface of the insulating layer structure 110 and 160 may be divided into an inner region inside the blocking element 160, a blocking region in which the blocking element is positioned, and an outer region outside the blocking element 160. The blocking region may be positioned on a different level from the inner region and the outer region, and may be a stepped surface with a step. The inner region, the blocking region (or the stepped surface) and outer region of the lower surface of the insulating layer structure 110 and 160 may be referred to as a first surface, a second surface and a third surface, respectively. The second surface may surround the first surface, and the third surface may surround the second surface. In the insulating layer structure 110 and 160 of the semiconductor package 10 described with reference to FIGS. 1A to 1D, a portion of the lower surface of the insulating layer structures 110 and 160, in which the blocking element 160 is positioned, may be positioned on a level lower than other portions of the lower surface of the insulating layer structures. Due to the configuration of the insulating layer structure 110 and 160, the backspill portion 520 of the shielding layer 500 may be prevented from being in contact with the connection conductors 400. In the following description, a dam structure 160 and an insulating layer 110 may be described as a single insulating layer structure 110 and 160.

The semiconductor chip structure 200 may be disposed on the redistribution structure 100, and may include the semiconductor chip 210, the connection terminal 210P, a connection pillar 220 and a connection solder 230.

The semiconductor chip 210 may be disposed on the upper surface of the insulating layer 110, and may include a connection terminal 210P electrically connected to the redistribution layers 120. The semiconductor chip 210 may include a semiconductor wafer formed of semiconductor elements, such as silicon and germanium, or compound semiconductors such as silicon carbide (SiC), gallium arsenide (GaAs), indium arsenide (InAs) and indium phosphide (InP), and a semiconductor wafer integrated circuit (IC). The semiconductor chip 210 may be a bare IC without separate bumps or interconnection layers, but is not limited thereto, and may be a packaged-type IC. The integrated circuit may be a logic circuit (or ‘logic chip’) such as a central processing unit (CPU), a graphics processing unit (GPU), a field programmable gate array (FPGA), an application processor (AP), a digital signal processor, a cryptographic processor, a microprocessor, a microcontroller, an analog-to-digital converter, an application-specific IC (ASIC) or a memory circuit (or ‘memory chip’) including a volatile memory such as a dynamic RAM (DRAM), a static RAM (SRAM) and the like, and a non-volatile memory such as a phase change RAM (PRAM), a magnetic RAM (MRAM), a resistive RAM (RRAM), a flash memory and the like.

In one or more examples, the semiconductor chip structure 200 may include the connection pillar 220 and the connection solder 230 connecting the connection terminal 210P to the redistribution layer 120 disposed on the insulating layer 110. An underfill layer 290 may be disposed between the semiconductor chip 210 and the insulating layer 110. The underfill layer 290 may have a capillary underfill (CUF) structure, but the present disclosure is not limited thereto. Depending on the embodiments, the underfill layer 290 may have a molded underfill (MUF) structure integrated with the encapsulant 300.

In one or more examples, the encapsulant 300 may encapsulate at least a portion of the semiconductor chip 210 on the upper surface of the insulating layer 110. The encapsulant 300 may include, for example, a thermosetting resin such as an epoxy resin, a thermoplastic resin such as polyimide, or a resin impregnated with an inorganic filler, for example, prepreg, Ajinomoto Build-up Film (ABF), FR-4, Bismaleimide-Triazine (BT) and an epoxy molding compound (EMC). For example, the encapsulant 300 may include an EMC.

The connection conductors 400 may be disposed below the insulating layer 110. The connection conductors 400 may be electrically connected to the semiconductor chip 210 through the redistribution layers 120. The semiconductor package 10 may be connected to an external device such as a module substrate, a system board, or the like, through connection conductors 400. As an example, the connection conductors 400 may include a low melting point metal, for example, tin (Sn) or an alloy containing tin (Sn) (e.g., Sn—Ag—Cu). Depending on the embodiments, the connection conductors 400 may have a shape that is a combination of a pillar (or underbump metal) and a ball. The pillar may include copper (Cu) or an alloy of copper (Cu), and the ball may include a solder ball. Depending on the embodiments, the insulating layer 110 may include a resist layer protecting the connection conductors 400 from physical or chemical external damages.

In one or more examples, the shielding layer 500 may cover the side surfaces of the insulating layers 110 and upper and side surfaces of the encapsulant 300, and may cover at least a portion of the outer region of the lower surface of the insulating layer 110 positioned outside relative to the dam structure 160. The shielding layer 500 may include a body portion 510 covering the side surfaces of the insulating layer 110 and the upper and side surfaces of the encapsulant 300 and a backspill portion 520 covering at least a portion of the outer region of the lower surface of the insulating layer 110. The backspill portion 520 may be in contact with any one outer surface 160S1 of the outer surfaces 160S1, 160S2, 160S3 and 160S4 of the dam structure 160. A thickness 520t of the backspill portion 520 in a direction perpendicular to a direction in which the lower surface of the insulating layer 110 extends may be less than a thickness 510t of the body portion 510 in a direction perpendicular to a direction in which the side surface of the insulating layer 110 extends. The thickness 520t of the backspill portion 520 may be less than the thickness 160t of the dam structure 160. A lower end of the shielding layer 500 may be positioned on a level higher than the lower surface of the dam structure 160 (in the same sense, a blocking surface of the blocking element). In one or more examples, the lower end of the shielding layer 500 may refer to a portion of the shielding layer 500 positioned on the lowest level in a direction perpendicular to the direction in which the lower surface of the insulating layer 110 extends (e.g., Z direction). The lower end of the shielding layer 500 may be positioned on a level lower than the lower surface of the insulating layer 110. That is, in the direction perpendicular to the direction in which the lower surface of the insulating layer 110 extends, the lower end of the shielding layer 500 may be positioned between the lower surface of the insulating layer 110 and the lower surface of the dam structure 160. The lower end of the shielding layer 500 may be spaced apart from the lower surface of the dam structure 160.

In one or more examples, the shielding layer 500 may be a thin film formed along the surfaces of the insulating layer 110 and the encapsulant 300, and may include a conductive material for an electromagnetic interference (EMI) shielding, such as iron (Fe), nickel (Ni), gold (Au), silver (Ag), copper (Cu) or an alloy thereof. In one or more embodiments, the shielding layer 500 may include stainless steel (SUS). The shielding layer 500 may include at least one layer of conductive thin film. For example, the shielding layer 500 may be a three-layer thin film in which a stainless steel (SUS) film, a copper (Cu) film and a stainless steel (SUS) film are sequentially stacked. In one or more examples, EMI shielding may refer to the reflection and/or absorption of EM radiations using a material; the material acting as a shielding material prevents the penetration of radiations of high frequencies such as radio waves.

The semiconductor package according to the present disclosure may include the dam structure 160, that is, a blocking element, disposed on the lower surface of the insulating layer 110, thereby preventing the backspill portion 5420 that may be formed when forming the shielding layer 500 from contacting the connection conductors 400 so as to provide a semiconductor package with enhanced reliability.

In the following description, descriptions overlapping those described with reference to FIGS. 1A to 1D will be omitted. In addition, overlapping descriptions in each embodiment will be omitted.

FIGS. 2 to 4 are enlarged views of variations of region ‘A’ in FIG. 1A.

Referring to FIG. 2 together with FIGS. 1A and 1D, the backspill portion 520 of the shielding layer 500 may extend along the outer surface 160S1 of the dam structure 160 that is in contact therewith. A thickness 525t to which the backspill portion 520 extends may be greater than the thickness 520t of the backspill portion 520, and the lower end of the backspill portion 520 may be positioned on a level higher than the lower surface of the dam structure 160. Depending on the embodiments, the thickness 525t of the backspill portion 520 extending along the outer surface 160S1 of the dam structure 160 may be less than the thickness 520t of the backspill portion 520. In one or examples, a portion of the backspill portion 520 extending along the outer surface 160S1 may be integrally formed with a portion of the backspill portion 520 extending along the lower surface of the insulation layer 110.

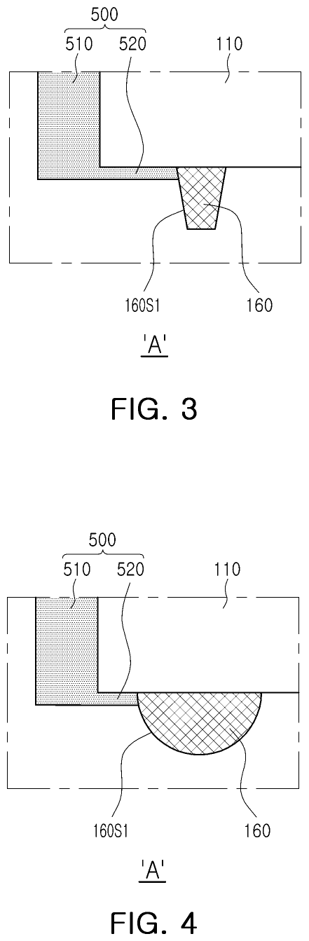

Referring to FIG. 3 together with FIGS. 1A and 1D, the side surfaces of the dam structure 160 may have inclined side surfaces so as to widen toward the lower surface of the insulating layer 110. In one or more embodiments, the outer surfaces 160S1, 160S2, 160S3 and 160S4 of the dam structure 160 may be inclined to be positioned further inward as the levels thereof decrease. For example, in direction away from the lower surface of the insulating layer 110, a thickness of the dam structure 160 decreases.

Referring to FIG. 4 together with FIGS. 1A and 1D, the lower surface of the dam structure 160 may be curved. The boundaries between the lower surface and the inner and outer surfaces of the dam structure 160 may vary, and a cross-section of the dam structure 160 in a direction perpendicular to the lower surface of the insulating layer 110 may have a semicircular or semielliptical shape. The cross-sectional shape of the dam structure 160 is not limited to the shape shown in FIGS. 1D and 2 to 4 and may vary. For example, the cross-sectional shape of the insulating layer 110 of the dam structure 160 in a direction perpendicular to the bottom may be triangular.

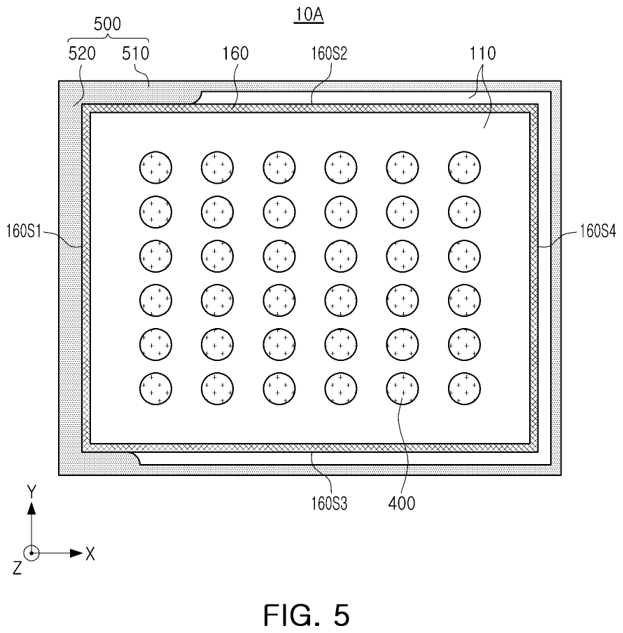

FIGS. 5 to 8 are bottom views illustrating semiconductor packages according to one or more exemplary embodiments.

Referring to FIG. 5 together with FIGS. 1A and 1D, in a semiconductor package 10A, a backspill portion 520 of a shielding layer 500 may simultaneously be in contact with one outer surface 160S1 of a dam structure 160 and both outer surfaces 160S2 and 160S3 adjacent to the outer surface 160S1. A thickness of the backspill portion 520 in a direction perpendicular to a lower surface of an insulating layer 110 may be formed differently for each of the contacting outer surfaces 160S1, 160S2 and 160S3.

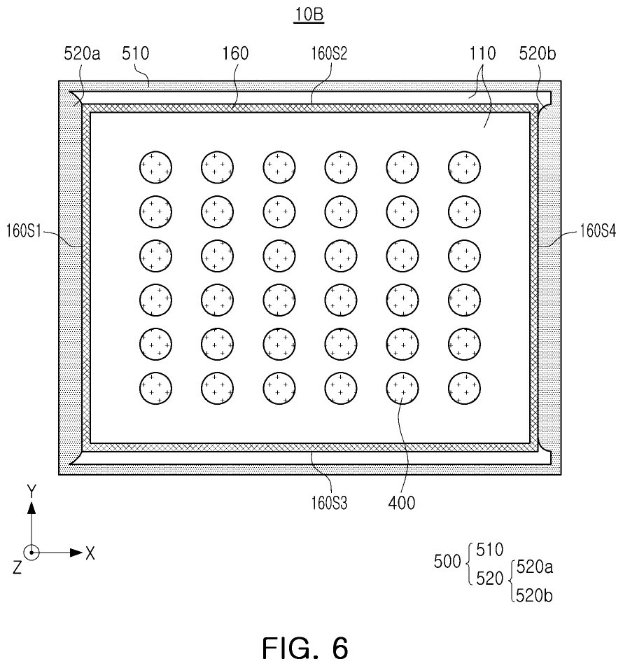

Referring to FIG. 6, in a semiconductor package 10B, a backspill portion 520 may include a first backspill portion 520a in contact with an outer surface 160S1 of a dam structure 160, and a second backspill portion 520b in contact with an outer surface 160S4 opposite to the outer surface 160S1. Areas, shapes or the like of the portions of the first and second backspill portions 520a and 520b in contact with the outer surfaces 16S1 and the outer surface 160S4 opposite thereto may be modified in various manners. In one or more embodiments, the first backspill portion 520a may simultaneously be in contact with the outer surface 160S1 and outer surfaces 160S2 and 160S3 connected to the outer surface 160S1.

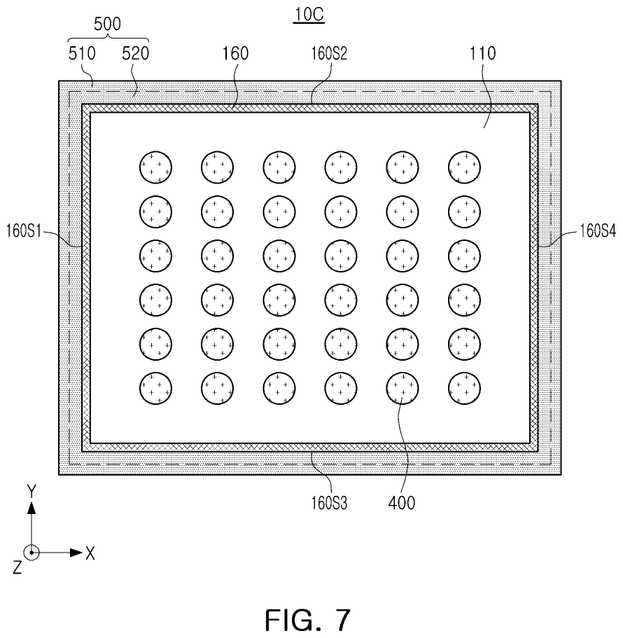

Referring to FIG. 7, in a semiconductor package 10C, a backspill portion 520 of a shielding layer 500 may cover an entire outer region of a lower surface of an insulating layer 110 positioned outside relative to a dam structure 160, and may simultaneously be in contact with each of outer surfaces 160S1, 160S2, 160S3 and 160S4 of the dam structure 160. A shape in which the backspill portion 520 is in contact with each of the outer surfaces 160S1, 160S2, 160S3 and 160S4 of the dam structure 160 may be the shape of the backspill portion 520 illustrated in FIG. 1D or FIG. 2, but is not limited thereto. The shape of the backspill portion 520 of the shielding layer 500 and its arrangement relationship the outer surfaces of the the dam structure 160 are not limited to FIGS. 5 to 7, and may be modified in various manners.

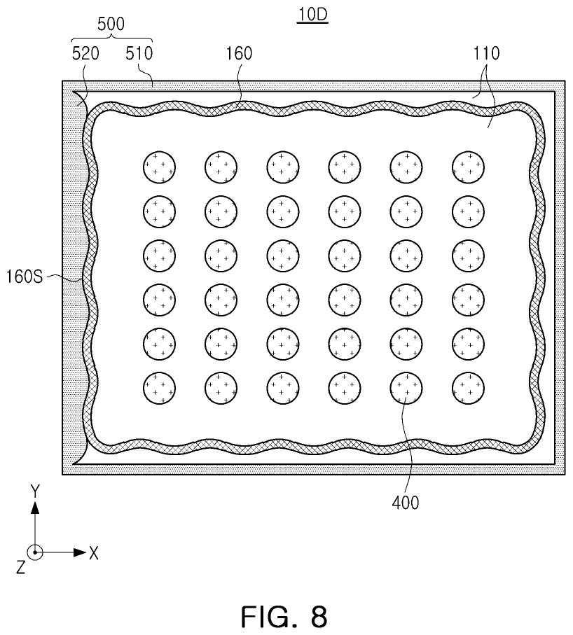

Referring to FIG. 8, in a semiconductor package 10D, a dam structure 160 may have a wave shape when viewed in a plan view. That is, an outer surface 160S of the dam structure 160 may not be parallel to any side surface of an insulating layer 110, and may be positioned further inside or further outside on a lower surface of the insulating layer 110 depending on the portions thereof. For examples, the outer surface 160S of the dam structure 160 may be non-linear.

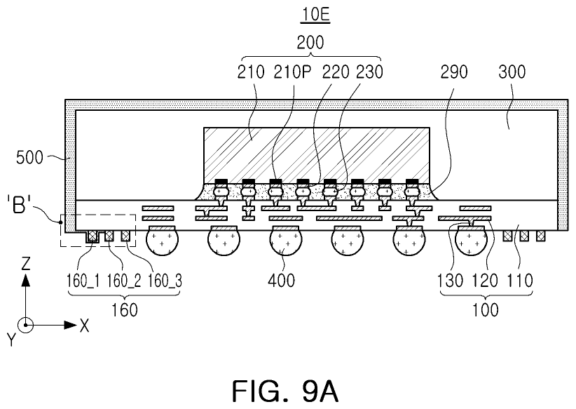

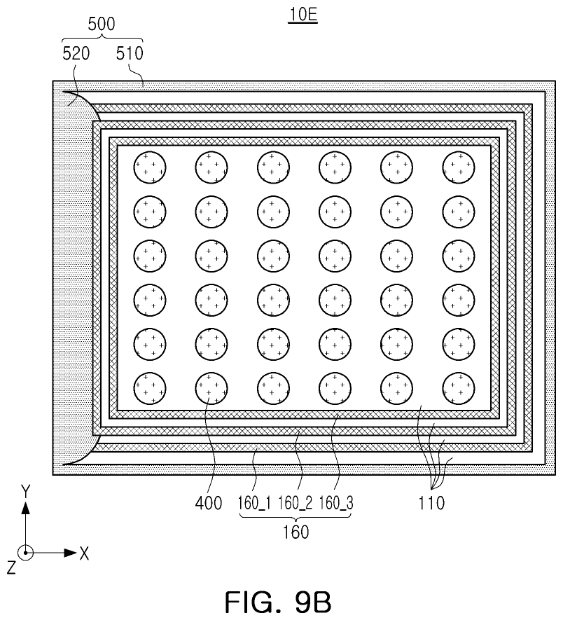

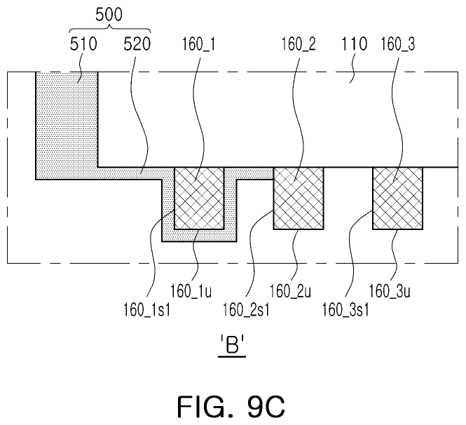

FIG. 9A is a cross-sectional view illustrating a semiconductor package according to one or more exemplary embodiments. FIG. 9B is a bottom view illustrating a semiconductor package according to one or more exemplary embodiments. FIG. 9B illustrates a bottom view of the semiconductor package 10E of FIG. 9A. FIG. 9C is an enlarged view of region ‘B’ in FIG. 9A.

Referring to FIGS. 9A to 9C, a dam structure 160 of the semiconductor package 10E may be comprised of a plurality of dam structures 160_1, 160_2 and 160_3. The plurality of dam structures 160_1, 160_2 and 160_3 may include a first dam structure 160_1 positioned on an outermost side of a lower surface of an insulating layer 110, a third dam structure 160_3 positioned on an innermost side thereof, and a second dam structure 160_2 positioned between the first dam structure 160_1 and the third dam structure 160_3. The first dam structure 160_1 positioned on the outermost side may be referred to as an outermost dam structure 160_1, and the third dam structure 160_3 positioned on the innermost side may be referred to as an innermost dam structure 160_3. As understood by one of ordinary skill in the art number of the plurality of dam structures 160_1, 160_2 and 160_3 is shown as three, but the number of the plurality of dam structures may be modified in various manners, such as two or more than three. During formation of the shielding layer, when a backspill portion 520 of a shielding layer 500 intrudes the lower surface of the insulating layer 110 inside with respect to the outermost dam structure 160_1, the second dam structure 160_2 positioned inside with respect to the outermost dam structure 160_1 may block the backspill portion 520. The backspill portion 520 may cover a portion of the lower surface as well as an outer surface 160_1s1 of the outermost dam structure 160_1, and may be in contact with an outer surface 160_2s1 (FIG. 9C) of the second dam structure 160_2. The backspill portion 520 may be blocked by the second dam structure 160_2 and spaced apart from the innermost dam structure 160_3. In one or more examples, the backspill portion 520 may also be in contact with an outer surface 160_3s1 of the innermost dam structure 160_3, but in this case, the backspill portion 520 may be blocked by the innermost dam structure 160_3 and advantageously spaced apart from connection conductors 400.

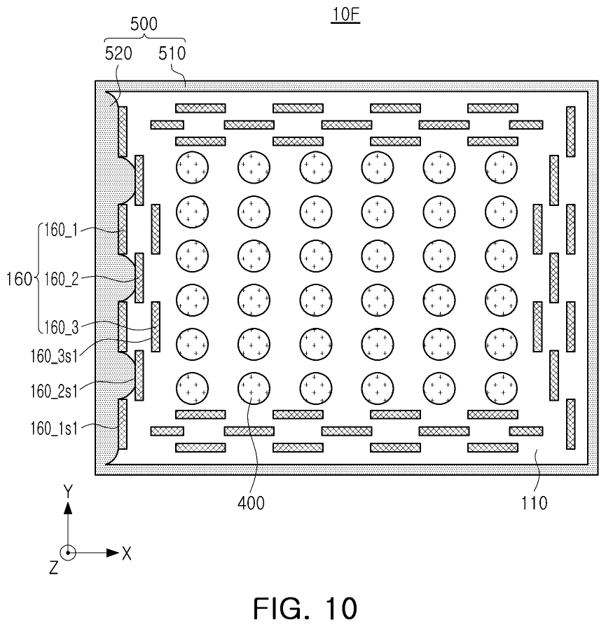

FIG. 10 is a bottom view illustrating a semiconductor package according to one or more exemplary embodiments. FIG. 10 illustrates a semiconductor package 10F, which is a variation of the semiconductor package 10E of FIG. 9B.

Referring to FIG. 10, a plurality of dam structures 160_1, 160_2 and 160_3 of a semiconductor package 10F may include a plurality of openings penetrating in the X- or Y-direction on a plane. For example, the plurality of dam structures 160_1, 160_2 and 160_3 of the semiconductor package 10F may be spaced apart from each other in the X or Y directions, thereby forming the openings. In order to block a backspill portion 520, the plurality of openings may include portions that do not overlap in a plane view. The backspill portion 520 may penetrate an opening of an outermost dam structure 160_1 and cover a portion of a lower surface of an insulating layer 110 inside with respect to the outermost dam structure 160_1, but may be blocked by a second dam structure 160_2 or an innermost dam structure 160_3. The backspill portion 520 may simultaneously contact an outer surface 160_1s1 of the outermost dam structure 160_1 and an outer surface 160_2s1 of the second dam structure 160_2. Depending on the embodiments, the backspill portion 520 may also contact an outer surface 160_3s1 of the innermost dam structure 160_3. By blocking a portion of an outer dam structure having an opening with an inner dam structure, the backspill portion 520 may be blocked from reaching connection conductors 400, thereby providing a semiconductor package with enhanced reliability.

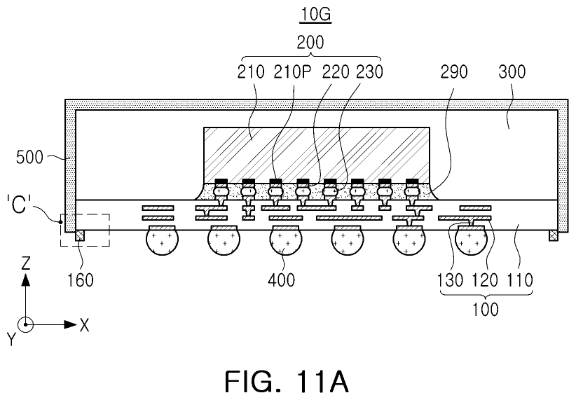

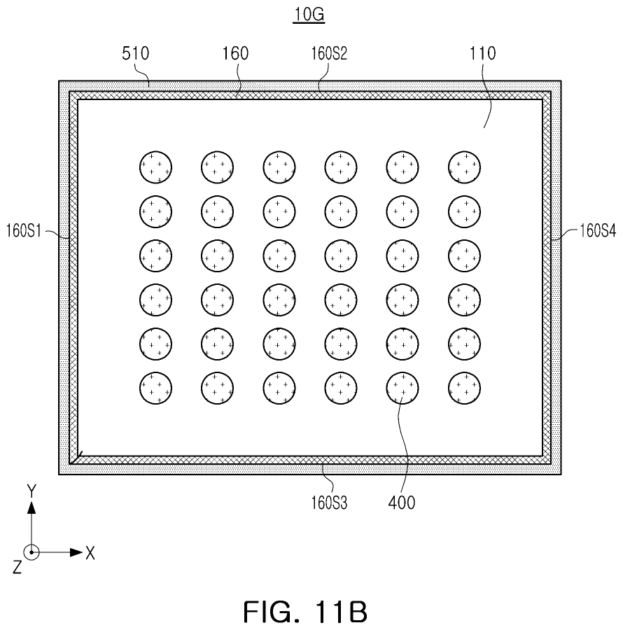

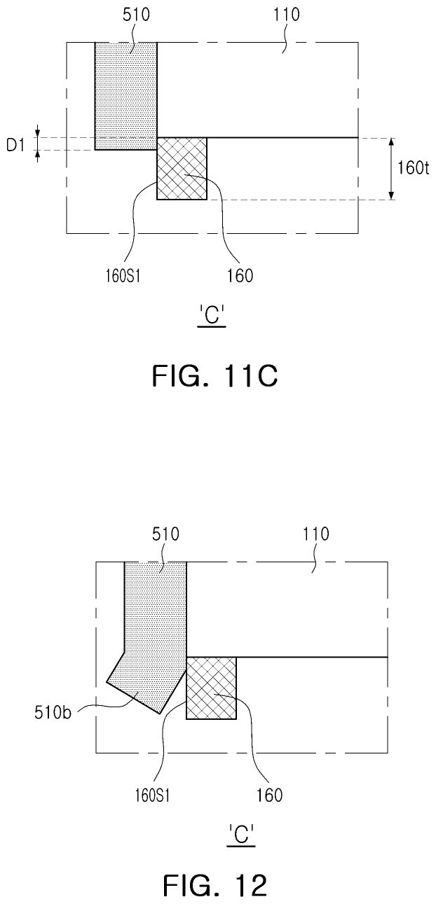

FIG. 11A is a cross-sectional view illustrating a semiconductor package according to one or more exemplary embodiments. FIG. 11B is a bottom view illustrating a semiconductor package according to one or more exemplary embodiments. FIG. 11C is an enlarged view of region ‘C’ in FIG. 11A. FIG. 11B illustrates a bottom view of the semiconductor package 10G of FIG. 11A.

Referring to FIGS. 11A to 11C, a dam structure 160 of the semiconductor package 10G may be disposed at edges of a lower surface of an insulating layer 110, and outer surfaces 160S1, 160S2, and 160S3 and 160S4 of the dam structure 160 may be coplanar with respective side surfaces of the insulating layer 110. A shielding layer 500 of the semiconductor package 10G may not have a backspill portion 520 previously described, and the shielding layer 500 may include a body portion 510. A lowermost end of the shielding layer 500 may be lower than the lower surface of the insulating layer 110, and may be positioned on a level higher than a lower end of the dam structure 160. A level difference D1 (FIG. 11C) between the lower surface of the insulating layer 110 and the lowermost end of the shielding layer 500 may be less than a thickness 160t of the dam structure 160 in a direction perpendicular to a direction in which the lower surface of the insulating layer 110 extends. The semiconductor package 10G may block a formation of the backspill 520, thereby providing a semiconductor package with enhanced reliability.

FIG. 12 is an enlarged view of a variation of region ‘C’ area of FIG. 11A.

Referring to FIG. 12 together with FIGS. 11A and 11B, a shielding layer 500 may include a burr portion 510b extending from a lower end of a body portion 510 and spaced apart from a dam structure 160. The dam structure 160 may block the burr portion 510b from extending to an inside of a lower surface of an insulating layer 110. Therefore, the dam structure 160 advantageously prevents a failure that may be caused by the burr portion 510b in contact with connection conductors 400 on the lower surface of the insulating layer 110, thereby providing a semiconductor package with enhanced reliability.

FIG. 13A is a cross-sectional view illustrating a semiconductor package according to one or more exemplary embodiments. FIG. 13B is a bottom view illustrating a semiconductor package according to one or more exemplary embodiments. FIG. 13c is an enlarged view of region ‘D’ in FIG. 13A. FIG. 13B illustrates a bottom view of the semiconductor package 10H of FIG. 13A.

Referring to FIGS. 13A to 13C, the semiconductor package 10H may include a trench structure 170 as a blocking element according to one or more embodiments. Although only the trench structure 170 is illustrated in FIGS. 13A-13C, as understood by one of ordinary skill in the art, the semiconductor package 10H may include both the dam structure 160 described above and the trench structure 170. The trench structure 170 may be arranged to surround connection conductors 400 on a lower surface 110U of an insulating layer 110. The lower surface 110U of the insulating layer 110 may include a first surface 110U1, a second surface 110U2 surrounding the first surface 110U1—the trench structure 170 is positioned on the second surface 110U2—and a third surface 110U3 surrounding the second surface 110U2. The first surface 110U1, the second surface 110U2 and the third surface 110U3 may be referred to as an inner region, a blocking region and an outer region, respectively. The second surface 110U2 may be positioned on a level higher than the first surface 100U1 and the third surface 100U3, and the second surface 110U2 may have a step from the first surface 110U1 and the third surface 110U3. The first surface 110U1 may be positioned on a first level, the second surface 110U2 may be positioned on a second level, and the third surface 110U3 may be positioned on a third level. The second level may be a level higher than the first and third levels. A shielding layer 500 of the semiconductor package 10H including the trench structure 170 may include only a body portion 510 without the backspill portion 520 described with reference to FIGS. 1A to 1D. A lower end of the shielding layer 500 may be positioned on a level higher than the third level. A level difference D2 (FIG. 13C) between the lower end of the shielding layer 500 and the third level may be less than a level difference 170t between the second level and the third level. The level difference 170t between the second level and the third level may be 0.5 μm to 50 μm, and depending on the embodiments, may be 1 μm to 30 μm, 5 μm to 50 μm or 5 μm to 15 μm. If the level difference 170t between the second level and the third level is less than 0.5 μm, a blocking effect may decrease, and if it is greater than 50 μm, a process cost may increase and reliability may decrease. A width 170w of the trench structure 170, for example, a width 170w of the second surface in a direction parallel to the lower surface 110U of the insulating layer 110, may be 0.5 μm to 50 μm, and depending on the embodiments, may be 1 μm to 30 μm, 5 μm to 50 μm or 5 μm to 15 μm. If the width 170t of the trench structure 170 is less than 0.5 μm, process difficulty may increase, and if it is greater than 50 μm, a blocking effect and reliability may decrease.

The semiconductor package 10H including the trench structure 170 may prevent a formation of a backspill portion 520 or block a contact with connection conductors 400 even if a backspill portion 520 occurs, thereby providing a semiconductor package with enhanced reliability.

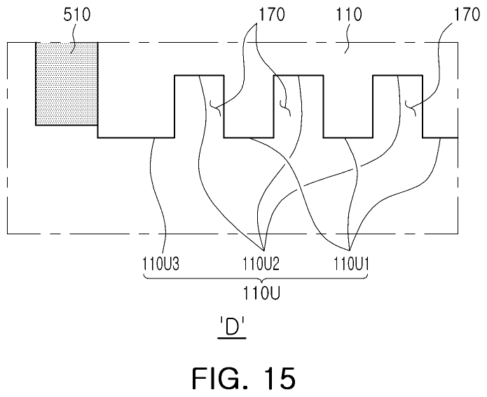

FIGS. 14 and 15 are enlarged views of variations of region ‘D’ in FIG. 13A

Referring to FIG. 14 together with FIG. 13A, a trench structure 170, which is a blocking element, may have side surfaces in which a width therebetween becomes narrower in a direction from a first or third surface 110U1 or 110U3 to a second surface 110U2 of an insulating layer 110. For examples, a width of the trench 170 becomes narrower in a direction towards the lower surface 110 of the insulation layer. In one or more examples, depending on the embodiments, the trench structure 170 may have side surfaces in which a width therebetween becomes narrower in a direction from the second surface 110U2 to the first or third surface 110U1 or 110U3 of the insulating layer 110. Such shapes may be modified in various manners depending on a process method for forming the trench structure 170.

Referring to FIG. 15 together with FIG. 13A, a trench structure 170 may include a plurality of trench structures 170. In this case, a first surface 110U1 positioned on a first level and a second surface 110U2 positioned on a second level may be alternately arranged from a center of a lower surface 110U of the insulating layer 110 toward edges thereof. In this case, a third surface 110U3 positioned on the third level may also be positioned on the outermost side. The third level may be the same as the first level. In FIG. 15, side surfaces of the trench structure 170 are shown perpendicular to the lower surface 110U of the insulating layer 110, but the present disclosure is not limited thereto. Depending on the embodiments, the trench structure 170 may have side surfaces in which a width therebetween becomes narrower in a direction from the first or third surface 110U1 or 110U3 to the second surface 110U2 of the insulating layer 110, as shown in FIG. 14. In one or more examples, the trench structure 170 may have side surfaces in which a width therebetween becomes narrower in a direction from the second surface 110U2 to the first or third surface 110U1 or 110U3 of the insulating layer 110. The number and shape of the trench structure 170 are not limited.

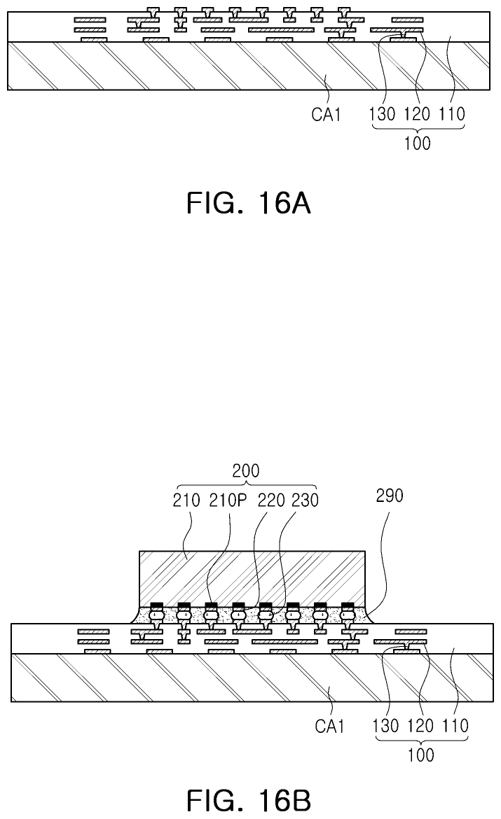

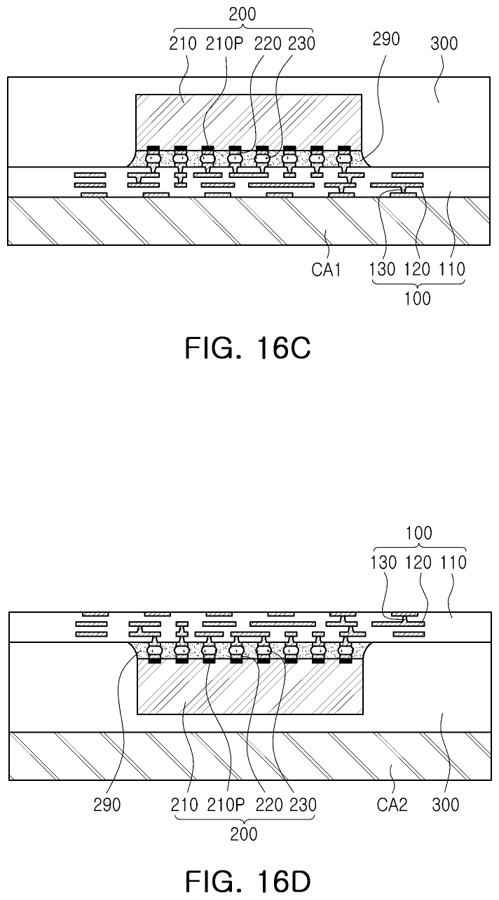

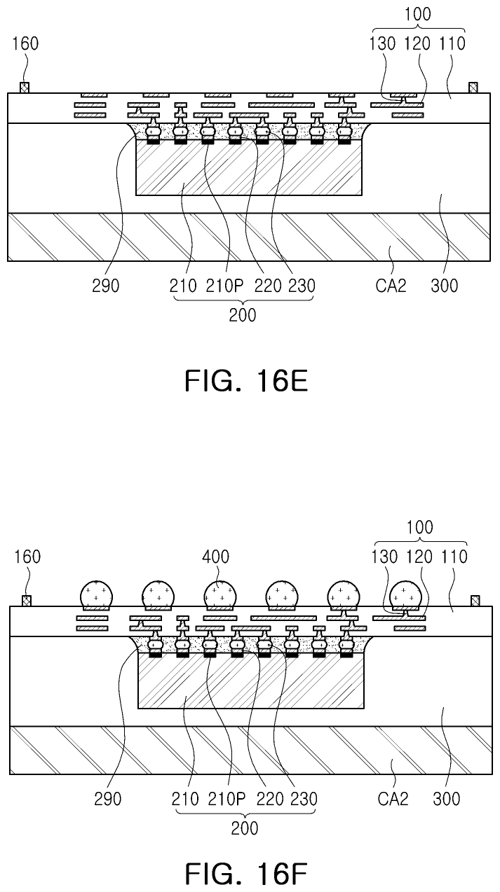

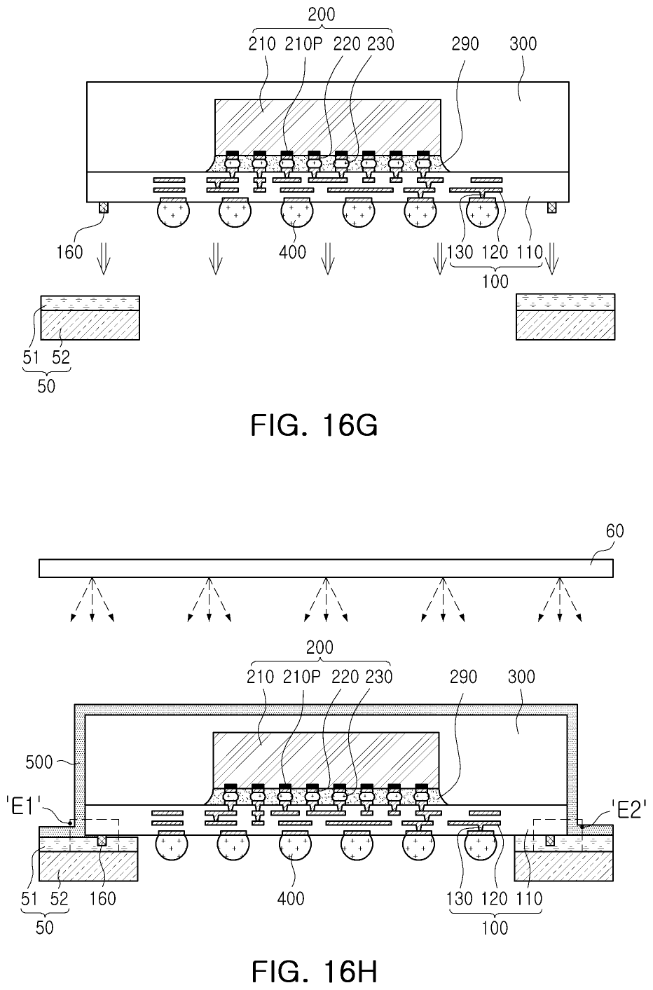

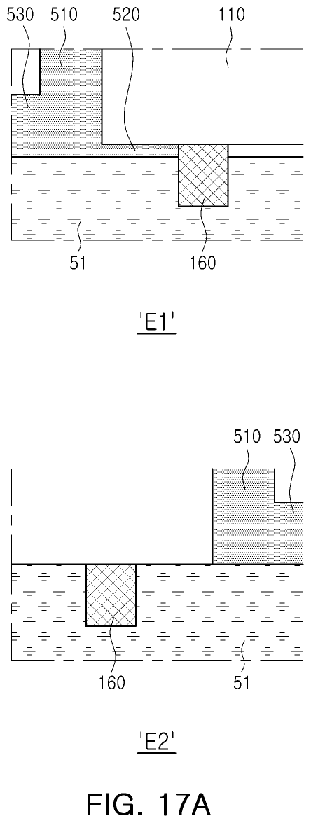

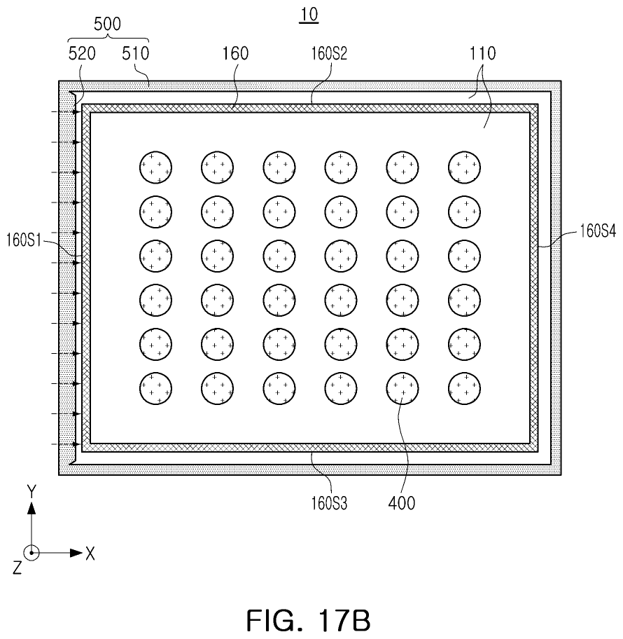

FIGS. 16A to 16H are cross-sectional views of a process sequence illustrating a method of manufacturing a semiconductor package according to one or more exemplary embodiments. FIG. 17A is enlarged views of region ‘E1’ and region ‘E2’ in FIG. 16H. FIG. 17B is a bottom view with respect to the cross-section view of FIG. 16H. FIGS. 16A to 17B illustrate a manufacturing method for the semiconductor package 10 of FIG. 1A.

Referring to FIG. 16A, a redistribution structure 100 including an insulating layer 110, redistribution layers 120, and redistribution vias 130 may be formed on a first carrier CA1.

For example, the first carrier CA1 may be formed by sequentially coating a polymer layer containing a curable resin and a metal layer containing nickel (Ni), titanium (Ti), or the like, on a copper clad laminate (CCL). The insulating layer 110 may be formed by sequentially applying and curing a photosensitive material, for example, PID on the carrier CA1. The redistribution layers 120 and the redistribution vias 130 may be formed by performing an exposure process and a development process to form a via hole penetrating the insulating layer 110 and patterning a metal material on the lower insulating layer 111 using a plating process. The redistribution layers 120 may also be formed on an upper surface of the insulating layer 110, and a barrier layer containing nickel (Ni), gold (Au) or the like may be formed.

Referring to FIG. 16B, a semiconductor chip structure 200 may be mounted on the insulating layer 110. The semiconductor chip structure 200 may be mounted using a flip-chip method. As understood by one of ordinary skill in the art, in a flip-chip method, an active area of the chip is “flipped over” facing downward. Instead of facing up and bonded to the package leads with wires from the outside edges of the chip, any surface area of the flip chip can be used for interconnection. In one or more examples, after the semiconductor chip structure 200 is flipped, the dam structure 160 may be formed. The semiconductor chip structure 200 may be electrically connected to the redistribution layers 120 through a connection pillar 220 and a connection solder 230 formed on a connection terminal 210P. An underfill layer 290 may be formed between the semiconductor chip 210 and the insulating layer 110. The underfill layer 290 may be formed using a CUF process, but the present disclosure is not limited thereto.

Referring to FIG. 16C, an encapsulant 300 may be formed to encapsulate at least a portion of the semiconductor chip structure 200. An upper surface of the encapsulant 300 may be formed at a level higher than an upper surface of the semiconductor chip structure 200. The encapsulant 300 may be formed, for example, by applying and curing an EMC.

Referring to FIG. 16D, a second carrier CA2 may be formed on the encapsulant 300, and the package may be turned over to proceed with the subsequent processes. The first carrier CA may be removed to expose the lower surface of the insulating layer 110 (an upper surface in FIG. 16D) and one surface of the redistribution layers 120 positioned on the uppermost portion (with respect to FIG. 16D).

Referring to FIG. 16E, a dam structure 160 may be formed on an upper surface (with respect to FIG. 16E) of the insulating layer 110. The dam structure 160 may be formed by applying a photosensitive material, for example, PID, on the insulating layer 110 and then using a photolithography process. The dam structure 160 may be formed using positive photoresist or negative photoresist depending on the desired shape of the dam structure 160.

Referring to FIG. 16F, connection conductors 400 may be formed in contact with the exposed redistribution layers 120. The subsequent processes can be performed by turning over the package again, and the second carrier CA2 may be removed.

Referring to FIG. 16G, in order to form a shielding layer 500 in FIG. 1A, the semiconductor package may be attached onto a shielding layer forming apparatus 50 including an adhesive member 51 and a support member 52. The adhesive member 51 may be an adhesive film coated with an adhesive on at least one surface thereof. The adhesive may use a pressure sensitive adhesive (PSA), but is not limited thereto. For example, the adhesive member 51 may be a double-sided tape in which an adhesive is applied to both sides of a polyimide film. The support member 52 may be formed using a material that has rigidity capable of supporting the adhesive member 51 and processability that can be processed into a shape of an opening. For example, the support member 52 may be a stencil made of metal. An adhesive material layer for temporarily fixing the adhesive member 51 may be disposed on an upper surface of the support member 52, but the present disclosure is not limited thereto.

Referring to FIGS. 16H, 17A and 17B, after attaching the semiconductor package to the shielding layer forming apparatus 50, a preliminary shielding layer 510, 520 and 530 covering the semiconductor package and the adhesive member 51 may be formed using a coating member 60. The coating member 60 may form the preliminary shielding layers 510, 520 and 530 by performing a deposition process such as a PVD or a CVD. For example, the coating member 60 may be a sputtering device, but is not limited thereto. The preliminary shielding layers 510 and 520 may correspond to the body portion and backspill portion, respectively, described above.

In one or more examples, the dam structure 160 may penetrate a portion of the adhesive member 51, and a portion of the lower surface of the insulating layer 110 may contact the adhesive member 51. At this time, when an outer region of the lower surface of the insulating layer 110 positioned on the outside of the dam structure 160 is completely in contact with the adhesive member 51 or is embedded within the adhesive member 51 as in region ‘E2’, a backspill portion 520 may not be formed. However, when the outer region of the lower surface of the insulating layer 110 and the adhesive member 51 are spaced apart from each other as in region ‘E1’, a backspill portion 520 covering the lower surface of the insulating layer 110 may be formed. At this time, the dam structure 160, which is a blocking element, may block the backspill portion 520 from expanding into an inner region of the lower surface of the insulating layer 110. In this process, the backspill portion 520 may be formed to contact an outer surface 160S1 of the dam structure 160. However, the embodiments of the present disclosure advantageously prevent the backspill portion 520 from contacting the connection conductors 400.

Thereafter, referring to FIG. 1A together, the preliminary shielding layer portion 530 formed on the adhesive member 51 may be removed, while separating the semiconductor package from the shielding layer forming apparatus 50, and the semiconductor package 10 of FIG. 1A may be manufactured.

In the following description, descriptions overlapping those described with reference to FIGS. 16A to 17B will be omitted.

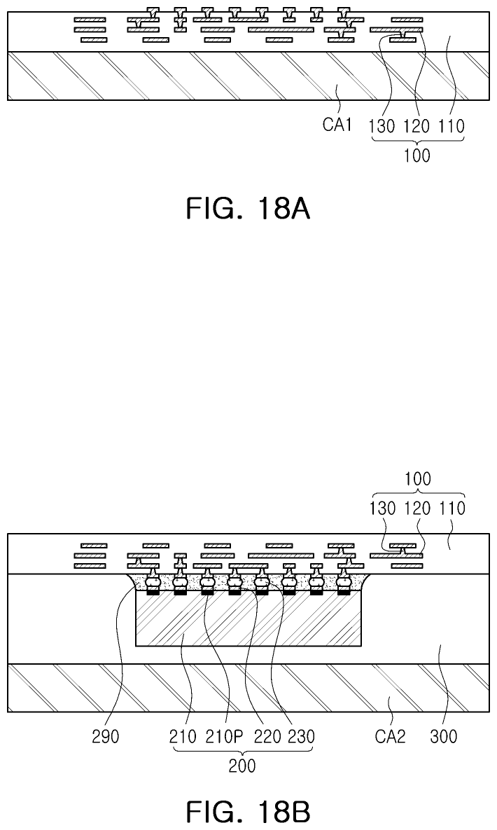

FIGS. 18A and 18B are cross-sectional views of a process sequence illustrating a method of manufacturing a semiconductor package according to one or more exemplary embodiments. FIGS. 18A and 18B illustrate parts of a manufacturing process for manufacturing the semiconductor package 10 of FIG. 1A.

Referring to FIG. 18A together with FIG. 1A, redistribution layers 120 may be formed to be spaced apart from a lower surface of an insulating layer 110. A thickness in a direction perpendicular to the lower surface of the insulating layer 110 of a dam structure 160 to be formed later may be determined depending on the distance between the lowermost redistribution layers 120 and the lower surface of the insulating layer 110.

Referring to FIG. 18B together with FIG. 16E, the dam structure 160 may be formed by etching an upper (with respect to FIG. 18B) surface of the insulating layer 110. The insulating layer 110 may be etched to the extent that an upper surface of the uppermost (with respect to FIG. 18B) redistribution layer 120 is exposed, and an unetched portion may remain to form the dam structure 160. According to this process, the dam structure 160 may be formed only through an etching process, without the need to additionally apply a photosensitive material as shown in FIG. 16E. The semiconductor package 10 of FIG. 1A may be manufactured through this process.

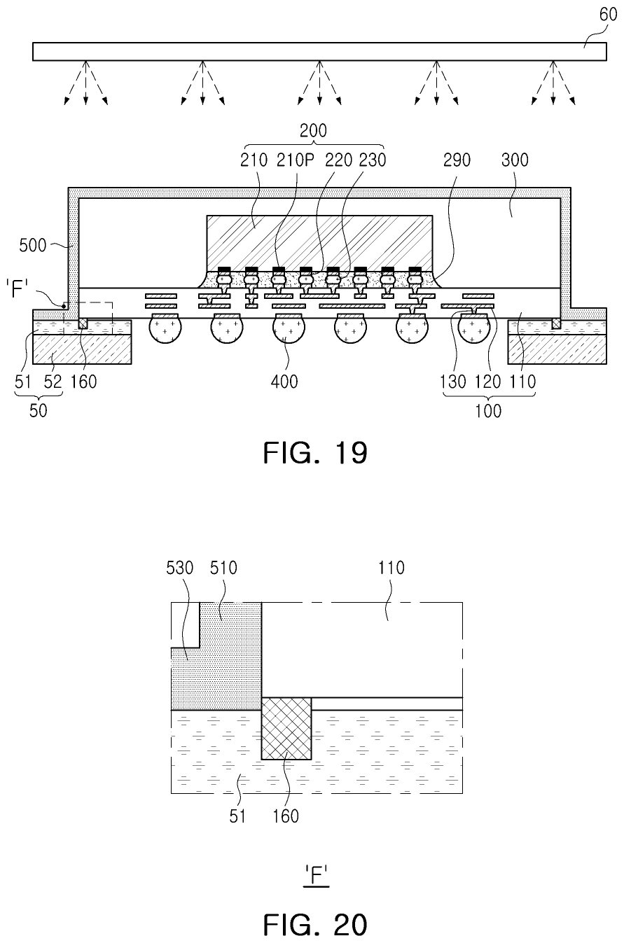

FIG. 19 is a cross-sectional view illustrating a method of manufacturing a semiconductor package according to one or more exemplary embodiments. FIG. 19 illustrates a process of forming the shielding layer 500 of the semiconductor package 10G of FIG. 11A. FIG. 20 illustrates an enlarged view of region ‘F’ in FIG. 19.

Referring to FIGS. 19 and 20, a dam structure 160 disposed on an outermost surface of a lower surface of an insulating layer 110 may be disposed to penetrate an adhesive member 51 of a shielding layer forming apparatus 50. A portion of an upper portion of the dam structure 160 may be positioned outside the adhesive member 51. For example, the insulating layer 110 may be spaced apart from the adhesive member 51. Referring to FIG. 11A together, through this process, a lower end of a shielding layer 500 may be formed to be positioned on a level lower than the lower surface of the insulating layer 110 and higher than a lower surface of the dam structure 160, and the formation of the backspill portion 520 may be blocked by the dam structure 160.

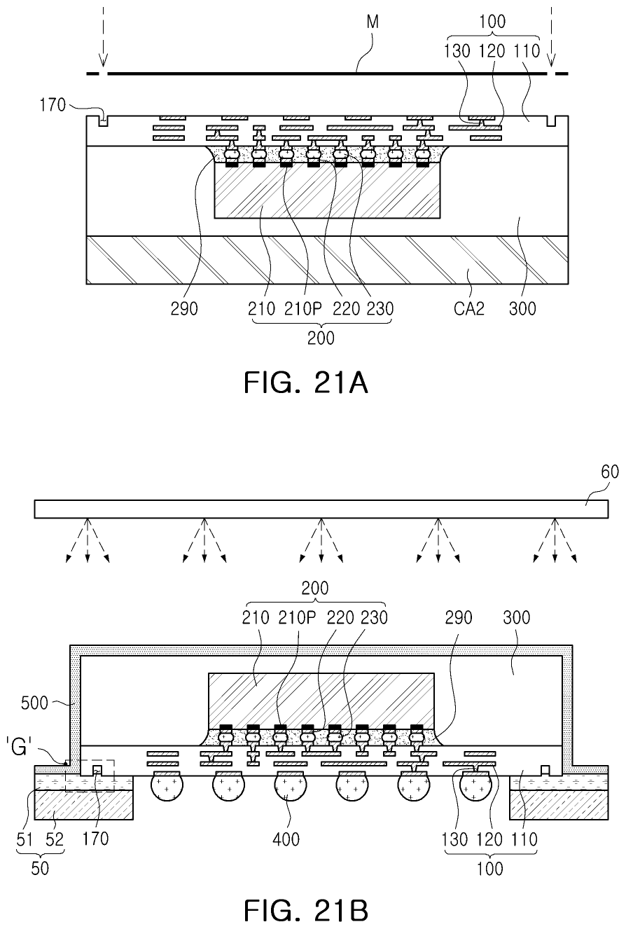

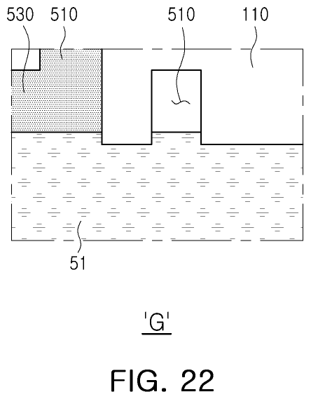

FIGS. 21A and 21B are cross-sectional views of a process sequence illustrating a method of manufacturing a semiconductor package according to one or more exemplary embodiments. FIGS. 21A to 21B illustrate parts of a process for manufacturing the semiconductor package 10H of FIG. 13A. FIG. 22 is an enlarged view of region ‘G’ in FIG. 21B.

Referring to FIG. 21A, after exposing an upper (with respect to FIG. 21A due to flip-chip method) surface of an insulating layer 110, a portion of an upper surface of an insulating layer 110 containing a photosensitive resin may be etched to form the trench structure 170 in FIG. 13A. Depending on the shape of the trench structure 170 to be formed, positive photoresist or negative photoresist may be used. In the case of FIG. 21A, a mask M is shown to expose a portion where the trench structure 170 is formed. However, depending on the type of resist used, the mask M may cover the portion where the trench structure 170 is formed.

Referring to FIGS. 21B and 22, the semiconductor package may be arranged so that the trench structure 170 is positioned on the adhesive member 51 of a shielding layer forming apparatus 50. A portion of the adhesive member 51 may be introduced into the trench structure 170, and a portion of the lower surface of the insulating layer 110 may be embedded in the adhesive member 51 to prevent a space between the adhesive member 51 and the lower surface of the insulating layer 110 in the adhesive member 51 from occurring. A lower end of the shielding layer 500 may be formed at a level higher than the lower surface of the insulating layer 110 and lower than an upper portion of the trench structure 170. Referring to FIG. 13B together, the lower end of the shielding layer 500 may be positioned on a level lower than a second surface 110U2 and higher than a third surface 110U3 and a first surface 110U1. During the process, the third surface 110U3 may be embedded in the adhesive member 51, thereby preventing a formation of a backspill portion 520.

According to embodiments of the present disclosure, by introducing a blocking element such as a dam structure or a trench structure to a lower surface of an insulating layer, defects that may occur when forming a shielding layer can be prevented and a semiconductor package with enhanced reliability can be provided.

While exemplary embodiments have been shown and described above, it will be apparent to those skilled in the art that modifications and variations could be made without departing from the scope of the present disclosure as defined by the appended claims.

What is claimed is:

1. A semiconductor package, comprising:
a semiconductor chip;
an insulating layer structure below the semiconductor chip, the insulating layer structure comprising a first surface facing the semiconductor chip and a second surface opposite to the first surface;
a plurality of redistribution layers disposed within the insulating layer structure and electrically connected to the semiconductor chip;
an encapsulant on the semiconductor chip and the first surface of the insulating layer structure;
a plurality of connection conductors on the second surface of the insulating layer structure and electrically connected to the plurality of redistribution layers; and
a shielding layer on a portion of the insulating layer structure and at least a portion of the encapsulant,
wherein the insulating layer structure further comprises a blocking element positioned on the second surface of the insulating layer structure and surrounding the plurality of connection conductors,
wherein the blocking element has a stepped surface positioned on a different level from the second surface of the insulating layer structure, and
wherein an end of the shielding layer is positioned between the stepped surface of the blocking element and the second surface of the insulating layer structure in a first direction perpendicular to a second direction in which the second surface of the insulating layer structure extends.

2. The semiconductor package of claim 1, wherein the end of the shielding layer is spaced apart from the stepped surface of the blocking element.

3. The semiconductor package of claim 1, wherein the blocking element is a dam structure having the stepped surface positioned on a level lower than the second surface of the insulating layer structure, and
an outer surface of the dam structure is coplanar with a third surface of the insulating layer structure that is perpendicular to the first surface and the second surface of the insulating layer structure.

4. The semiconductor package of claim 3, wherein the shielding layer comprises a body portion in contact with an entirety of the third surface of the insulating layer structure and a portion of the outer surface of the dam structure, and a burr portion extending from a first end of the body portion and spaced apart from the blocking element.

5. The semiconductor package of claim 1, wherein the blocking element is a dam structure having the stepped surface positioned on a level lower than the second surface of the insulating layer structure, and
the second surface of the insulating layer structure comprises a first region on a first side of the dam structure and a second region on a second side of the dam structure,
wherein the second side of the dam structure is closer to an edge of the insulating layer structure than the first side of the dam structure is to the edge of the insulating layer structure.

6. The semiconductor package of claim 5, wherein the shielding layer comprises a body portion on a third surface of the insulating layer structure and a first surface and a second surface of the encapsulant, and a backspill portion on at least a portion of the second region of the second surface of the insulating layer,
wherein the third surface of the insulating layer structure is perpendicular to the first surface of the insulating layer structure and the second surface of the insulating layer structure, and
wherein the first surface of the encapsulant is perpendicular to the second surface of the encapsulant.

7. The semiconductor package of claim 6, wherein the backspill portion is in contact with an outer surface of the dam structure facing towards the second side of the dam structure.

8. The semiconductor package of claim 1, wherein the blocking element comprises a trench structure having the stepped surface positioned on a level higher than the first surface of the insulating layer structure, and
the trench structure defines a first region in which the plurality of connection conductors are arranged, a second region around the first region, and a blocking region between the first region and the second region.

9. A semiconductor package, comprising:
an insulating layer comprising a first surface and a second surface opposing each other and a third surface perpendicular to the first surface and the second surface;
a plurality of redistribution layers within the insulating layer;
a semiconductor chip facing the first surface of the insulating layer and electrically connected to the plurality of redistribution layers;
an encapsulant on at least a portion of the semiconductor chip and the first surface of the insulating layer;
a plurality of connection conductors on the first surface of the insulating layer and electrically connected to the plurality of redistribution layers;
at least one dam structure on the second surface of the insulating layer and surrounding the plurality of connection conductors; and
a shielding layer covering a portion of the insulating layer and a portion of the encapsulant,
wherein the second surface of the insulating layer comprises a first region positioned on a first side of the at least one dam structure, and a second region positioned on a second side of the at least one dam structure, and the plurality of connection conductors are arranged in the first region,
wherein the second side of the at least one dam structure is closer to an edge of the insulating layer than the first side of the at least one dam structure is to the edge of the insulating layer,
wherein the shielding layer comprises a body portion covering the encapsulant and the third surface of the insulating layer, and a backspill portion covering at least a portion of the second region of the second surface of the insulating layer, and
wherein a thickness of the backspill portion in a first direction perpendicular to the second surface of the insulating layer is less than a thickness of the body portion in a second direction perpendicular to the third surface of the insulating layer.

10. The semiconductor package of claim 9, wherein the backspill portion is in contact with at least a portion of an outer surface of the at least one dam structure.

11. The semiconductor package of claim 9, wherein the at least one dam structure has a surface inclined to widen toward the second surface of the insulating layer.

12. The semiconductor package of claim 9, wherein a thickness of the at least one dam structure in the first direction is 5 μm to 50 μm, and a width of the at least one dam structure in the second direction is 5 μm to 50 μm.

13. The semiconductor package of claim 9, further comprising a plurality of dam structures comprising the at least one dam structure,
wherein the plurality of dam structures comprise an innermost dam structure adjacent to a connection conductor from the plurality of connection conductors and an outermost dam structure adjacent to the third surface of the insulating layer, and
wherein the backspill portion covers a portion of an outer surface of the outermost dam structure and is spaced apart from the innermost dam structure.

14. The semiconductor package of claim 9, wherein the insulating layer and the at least one dam structure comprise the same photosensitive resin.

15. A semiconductor package, comprising:
a semiconductor chip;
an insulating layer below the semiconductor chip, the insulating layer comprising first surface facing the semiconductor chip, a second surface opposite to the first surface, and a third surface between the first surface and the second surface, wherein the third surface is perpendicular to the first surface and the second surface;
a plurality of redistribution layers within the insulating layer and electrically connected to the semiconductor chip;
an encapsulant on the semiconductor chip and the first surface of the insulating layer;
a plurality of connection conductors on the second surface of the insulating layer and electrically connected to the plurality of redistribution layers; and
a shielding layer covering the third surface of the insulating layer and a first surface and second surfaces of the encapsulant, wherein the first surface of the encapsulant is perpendicular to the second surfaces of the encapsulant,
wherein the second surface of the insulating layer comprises a first portion positioned on a first level, a second portion positioned on a second level higher than the first level, and surrounding the first portion, and a third portion positioned on a third level lower than the second level and surrounding the second portion;
wherein the plurality of connection conductors are disposed on the first portion of the second surface of the insulating layer, and
wherein an end of the shielding layer is positioned on a level, higher than the third level.

16. The semiconductor package of claim 15, wherein the end of the shielding layer is positioned on a level, lower than the second level.

17. The semiconductor package of claim 15, wherein the first level and the third level are positioned on the same level.

18. The semiconductor package of claim 15, wherein a width of the second surface is 5 μm to 50 μm.

19. The semiconductor package of claim 15, wherein a level difference between the second level and the third level is 5 μm to 50 μm.

20. The semiconductor package of claim 15, wherein a width of the second portion is less than a distance between the first portion and the third portion in a direction parallel to the second surface of the insulating layer.
